(19) United States
(12) Patent Application Publication
(10) Pub. No.: US 2026/0178798 A1
(43) Pub. Date: Jun. 25, 2026

(54) Method for Testing the Robustness of a Machine Learning Algorithm for Classifying Objects in an Environment of a Motor Vehicle

(71) Applicant: Robert Bosch GmbH, Stuttgart (DE)

(72) Inventors: Arnd Gazecki, Muenchen (DE); Sinan Hasirlioglu, Ingolstadt (DE)

(21) Appl. No.: 19/127,369

(22) PCT Filed: Nov. 8, 2023
(86) PCT No.: PCT/EP2023/081077

§ 371 Date: May 5, 2025

(30) Foreign Application Priority Data
Nov. 10, 2022 (DE) 10 2022 211 904.5

(51) Int. Cl. G06F 30/27; G06V 10/764; G06V 10/776; G06V 20/58

(52) U.S. Cl. CPC G06F 30/27; G06V 10/764; G06V 10/776; G06V 20/58

(57) ABSTRACT

A method is for testing a robustness of a machine learning algorithm for classifying objects in an environment of a motor vehicle. The machine learning algorithm is trained to classify objects in image data representing an environment of the motor vehicle. The method includes providing image data showing an environment of the motor vehicle. The image data contain a depiction of at least one object. The method also includes modifying the depiction of the at least one object such that it appears distorted, and simulating control of the motor vehicle based on objects classified by the machine learning algorithm in the modified depiction of the at least one object in order to test the robustness of the machine learning algorithm.

The invention relates to a method for testing the robustness of a machine learning algorithm, which can check the influence of external factors or interventions on the control of the vehicle and increase the safety of controlling the vehicle based on the machine learning algorithm.

Machine-learning algorithms are based on using statistical methods to train a data processing system such that it may perform a specific task without having been explicitly programmed to do so. The goal of machine learning is to construct algorithms that may learn and make predictions from data. These algorithms create mathematical models with which data may be classified, for example.

Robustness further refers to the ability of the machine learning algorithm to withstand changes, such as external attacks. Regarding external attacks, a distinction is generally made between a white-box attack, in which the attacker has knowledge about the structure of the machine learning algorithm, the nature of the training process, and the available data used to train the machine learning algorithm, and a black-box scenario, in which an attacker does not have this knowledge, but only sees the input data and the results that the network outputs.

Such machine learning algorithms are used when controlling a driver assistance system of a motor vehicle or operating an autonomously driving motor vehicle. The machine learning algorithm may be configured to classify objects represented in environmental data of the motor vehicle, such as road signs or traffic lights, and the motor vehicle, driver assistance system, or autonomously driving motor vehicle is controlled based on the classified objects. However, particularly when controlling a motor vehicle, high requirements are placed on the safety and thus also on the robustness of such a machine learning algorithm in order to avoid safety-critical situations as much as possible.

A method for training a neural network is known from publication DE 10 2019 209 560 A1, wherein the method comprises providing a training dataset with training images showing a vehicle environment from the perspective of a vehicle, wherein a plurality of the training images show traffic signs, generating additional training images by augmenting training images showing a traffic signs, by augmenting a training image showing a traffic sign, by partially covering the traffic sign and/or augmenting a training image showing a variable traffic sign, by changing the lighting state of one or more lighting elements of the variable traffic sign and training the neural network based on at least the augmented training images.

The invention is based on the task of reliably testing the robustness of a machine learning algorithm for classifying objects in an environment of a motor vehicle without significant effort.

The task is solved by a method for testing the robustness of a machine learning algorithm for classifying objects in an environment of a motor vehicle according to the features of claim 1.

The task is also solved by a system for testing the robustness of a machine learning algorithm for classifying objects in an environment of a motor vehicle according to the features of claim 8.

### DISCLOSURE OF THE INVENTION

According to one embodiment of the invention, this task is solved by a method for testing the robustness of a machine learning algorithm for classifying objects in an environment of a motor vehicle, wherein the machine learning algorithm is trained to classify objects in image data representing an environment of the vehicle, and wherein the method comprises providing image data showing an environment of the vehicle, wherein the image data contain a depiction of at least one object, modifying the depiction of the at least one object such that it appears distorted, and simulating a control of the motor vehicle based on objects classified by the machine learning algorithm based on the modified depiction of the at least one object in order to test the robustness of the machine learning algorithm.

Image data refers to data that can be rendered as an image or graphic with the help of a specific program. The fact that an object is represented in image data means that the corresponding image data shows the object or contains a depiction of the object.

The manipulation or modification of the depiction of the object in a way that makes it appear distorted means that the depiction of the object is altered in a realistic yet subtle manner, for example, to simulate an external attack.

Thus, a method is specified that can be used to identify or detect safety-relevant or safety-critical aspects early on, particularly during the development of the machine learning algorithm. Based on the corresponding test results, it can be further checked whether the algorithm is robust enough against external influences, such as attacks from the outside, and thus suitable for controlling a motor vehicle.

The ability to respond early to potential safety-relevant aspects at an early stage, wherein the method can be used without knowledge of the structure of the machine learning algorithm, of the type of training method and of the available data with which the machine learning algorithm was trained, also has the advantage that the time until the machine learning algorithm can actually be used to classify objects in a vehicle environment can be reduced, while at the same time resources required for (re)training or optimizing the machine learning algorithm or making it more robust, such as storage capacities, can be saved.

Overall, a method is specified that can reliably and efficiently test the robustness of a machine learning algorithm for classifying objects in an environment of the motor vehicle.

The step of modifying the depiction of the at least one object may comprise modifying the depiction of the at least one object such that the object is incorrectly classified by the machine learning algorithm, and/or modifying the depiction of the at least one object based on how the object could be altered by a third party, and/or modifying the depiction of the at least one object based on different light and/or weather conditions.

The fact that the depiction of the at least one object is modified such that it is incorrectly classified by the machine learning algorithm means that the machine learning algorithm assigns the object to a different class based on the modified depiction than the one to which it actually belongs, or does not assign it to any class, i.e. the classification result is distorted.

the fact that the depiction of the at least one object is modified based on how the object could be altered by third parties also means that realistic or expected changes in conditions and/or known external attacks could be simulated.

The fact that the depiction of at least one object is modified based on different light conditions further means that the depiction of the object is adapted to other possible light conditions. For example, road signs may be perceived differently depending on sunlight exposure. The fact that the depiction of at least one object is modified based on different weather conditions further means that the depiction of the object is adjusted to possible weather conditions, for example rain and/or fog.

The depiction of at least one object can thus be adjusted to all known, realistic, and expected changes in conditions in order to simulate the behavior of the machine learning algorithm and thus also of the motor vehicle in the presence of these known, realistic and expected changes.

In one embodiment, the step of modifying the depiction of at least one object includes applying an image processing algorithm.

An image processing algorithm is understood to be an algorithm that is designed to alter or modify image data. For example, the objects may be rotated and/or scaled differently, or additional objects may be attached to the actual object.

Modifying the depiction of the at least one object can thus be done using known and common algorithms without the need for complex and resource-intensive adjustments.

In a further embodiment, the step of modifying the depiction of the at least one object comprises applying a machine learning algorithm that is trained to simulate external interventions.

The fact that the machine learning algorithm is trained to simulate external attacks means that the machine learning algorithm is an adversarial generator or is designed to manipulate the image data for the machine learning algorithm.

The depiction can thus be automatically adjusted as precisely as possible to known patterns of manipulation or change.

Furthermore, the image data may be sensor data recorded by environmental sensors of the motor vehicle.

A sensor, which is also referred to as a detector or (measurement) sensor or (measuring) probe, is a technical component that can record certain physical or chemical characteristics and/or the material characteristics of its surroundings qualitatively, or quantitatively as a measured variable.

An environmental sensor is further understood to be a sensor of the motor vehicle that is configured to capture data about an environment or at least a part of an environment of the motor vehicle.

The method for testing the robustness of the machine learning algorithm can thus be based on circumstances outside the actual data processing equipment on which the machine learning algorithm is tested.

Another embodiment of the invention provides a method for optimizing a machine learning algorithm for classifying objects in an environment of a motor vehicle, wherein the machine learning algorithm is trained to classify objects in image data representing an environment of the motor vehicle, and wherein the method comprises testing the robustness of the trained machine learning algorithm using a method described above for testing the robustness of a machine learning algorithm for classifying objects in an environment of a motor vehicle, in order to provide test results and optimize the machine learning algorithm based on the provided test results.

The fact that the machine learning algorithm is optimized in particular means that the machine learning algorithm is retrained based on the test results in order to avoid safety-critical situations based on objects classified by the machine learning algorithm, in particular when controlling the motor vehicle.

Thus, a method for optimizing a machine learning algorithm for classifying objects in an environment of a motor vehicle is provided, which is based on a method that can reliably and efficiently test the robustness of a machine learning algorithm for classifying objects in an environment of a motor vehicle. In particular, this is based on a method that can be used to identify or detect safety-relevant or safety-critical aspects early on, particularly during the development of the machine learning algorithm. Based on the corresponding test results, it can be further checked whether the algorithm is robust enough against external influences, such as attacks from the outside, and thus suitable for controlling a motor vehicle. The ability to respond to potential safety-relevant aspects early on, wherein the method can be used without knowledge of the structure of the machine learning algorithm, of the type of training method and of the available data with which the machine learning algorithm was trained, also has the advantage that the time until the machine learning algorithm can actually be used to classify objects in a vehicle environment can be reduced, while at the same time resources required for (re)training or optimizing the machine learning algorithm or making it more robust, such as storage capacities, can be saved.

With a further embodiment of the invention, a method for controlling a motor vehicle based on a machine learning algorithm is also provided, wherein the machine learning algorithm is trained to classify objects in image data representing an environment of the motor vehicle, wherein the method comprises providing a machine learning algorithm for classifying objects in an environment of the motor vehicle, wherein the machine learning algorithm has been optimized by a method described above for optimizing a machine learning algorithm for classifying objects in an environment of a motor vehicle, and controlling the motor vehicle based on the provided machine learning algorithm.

Thus, a method for controlling a motor vehicle based on a machine learning algorithm is provided, which is based on a method that can reliably and efficiently test the robustness of a machine learning algorithm for classifying objects in an environment of a motor vehicle. In particular, this is based on a method that can be used to identify or detect safety-relevant or safety-critical aspects early on, particularly during the development of the machine learning algorithm. Based on the corresponding test results, it can be further checked whether the algorithm is robust enough against external influences, such as attacks from the outside, and thus suitable for controlling a motor vehicle. The ability to respond to potential safety-relevant aspects early on, wherein the method can be used without knowledge of the structure of the machine learning algorithm, of the type of training method and of the available data with which the machine learning algorithm was trained, also has the advantage that the time until the machine learning algorithm can actually be used to classify objects in a vehicle environment can be reduced, while at the same time resources required for (re)training or optimizing the machine learning algorithm or making it more robust, such as storage capacities, can be saved.

With a further embodiment of the invention, a system for testing the robustness of a machine learning algorithm for classifying objects in an environment of a motor vehicle is also provided, wherein the machine learning algorithm is trained to classify objects in image data representing the environment of the motor vehicle, and wherein the system is configured to execute a method described above for testing the robustness of a machine learning algorithm for classifying objects in an environment of a motor vehicle.

Thus, a system is provided that can reliably and efficiently test the robustness of a machine learning algorithm for classifying objects in an environment of a motor vehicle. In particular, a system is specified that is designed to identify or detect safety-relevant or safety-critical aspects early, particularly during the development of the machine learning algorithm. Based on the corresponding test results, it can be further checked whether the algorithm is robust enough against external influences, such as attacks from the outside, and thus suitable for controlling a motor vehicle. The ability to respond to potential safety-relevant aspects early on, wherein the method can be used without knowledge of the structure of the machine learning algorithm, of the type of training method and of the available data with which the machine learning algorithm was trained, also has the advantage that the time until the machine learning algorithm can actually be used to classify objects in a vehicle environment can be reduced, while at the same time resources required for (re)training or optimizing the machine learning algorithm or making it more robust, such as storage capacities, can be saved.

With a further embodiment of the invention, a system for optimizing a machine learning algorithm for classifying objects in an environment of a motor vehicle is provided, wherein the machine learning algorithm is trained to classify objects in image data representing the environment of the motor vehicle, and wherein the system comprises a system described above for testing the robustness of a machine learning algorithm for classifying objects in an environment of a motor vehicle, which is configured to test the robustness of the trained machine learning algorithm in order to provide test results, and an optimization unit configured to optimize the machine learning algorithm based on the provided test results.

Thus, a system for optimizing a machine learning algorithm for classifying objects in an environment of a motor vehicle is provided, which is based on a system that can reliably and efficiently test the robustness of a machine learning algorithm for classifying objects in an environment of a motor vehicle. In particular, this is based on a system that is designed to identify or detect safety-relevant or safety-critical aspects early on, particularly during the development of the machine learning algorithm. Based on the corresponding test results, it can be further checked whether the algorithm is robust enough against external influences, such as attacks from the outside, and thus suitable for controlling a motor vehicle. The ability to respond to potential safety-relevant aspects early on, wherein the method can be used without knowledge of the structure of the machine learning algorithm, of the type of training method and of the available data with which the machine learning algorithm was trained, also has the advantage that the time until the machine learning algorithm can actually be used to classify objects in a vehicle environment can be reduced, while at the same time resources required for (re)training or optimizing the machine learning algorithm or making it more robust, such as storage capacities, can be saved.

With another embodiment of the invention, a system for controlling a motor vehicle based on a machine learning algorithm is provided, wherein the machine learning algorithm is trained to classify objects in image data representing the environment of the motor vehicle, and wherein the system comprises a provisioning unit configured to provide a machine learning algorithm for classifying objects in an environment of the motor vehicle, wherein the machine learning algorithm has been optimized by a system described above for optimizing a machine learning algorithm for classifying objects in an environment of a motor vehicle, and a control unit configured to control the motor vehicle based on the provided machine learning algorithm.

Thus, a system for controlling a motor vehicle based on a machine learning algorithm is provided, which is based on a system that can reliably and efficiently test the robustness of a machine learning algorithm for classifying objects in an environment of a motor vehicle. In particular, this is based on a system that is designed to identify or detect safety-relevant or safety-critical aspects early on, particularly during the development of the machine learning algorithm. Based on the corresponding test results, it can be further checked whether the algorithm is robust enough against external influences, such as attacks from the outside, and thus suitable for classifying objects in an environment of a motor vehicle. The ability to respond to potential safety-relevant aspects early on, wherein the method can be used without knowledge of the structure of the machine learning algorithm, of the type of training method and of the available data with which the machine learning algorithm was trained, also has the advantage that the time until the machine learning algorithm can actually be used to classify objects in a vehicle environment can be reduced, while at the same time resources required for (re)training or optimizing the machine learning algorithm or making it more robust, such as storage capacities, can be saved.

With a further embodiment of the invention, a computer program with program code to execute a method described above for testing the robustness of a machine learning algorithm for classifying objects in an environment of a motor vehicle when the computer program is executed on a computer.

With a further embodiment of the invention, a computer-readable data carrier with program code of a computer program is provided to execute a method described above for testing the robustness of a machine learning algorithm for classifying objects in an environment of a motor vehicle when the computer program is executed on a computer.

The computer program and the computer-readable data carrier each have the advantage that they are configured to execute a method with which the robustness of a machine learning algorithm for classifying objects in a motor vehicle environment can be tested reliably and efficiently. In particular, these are each configured to execute a method that is designed to identify or detect safety-relevant or safety-critical aspects early on, particularly during the development of the machine learning algorithm. Based on the corresponding test results, it can be further checked whether the algorithm is robust enough against external influences, such as attacks from the outside, and thus suitable for controlling a motor vehicle. The ability to respond to potential safety-relevant aspects early on, wherein the method can be used without knowledge of the structure of the machine learning algorithm, of the type of training method and of the available data with which the machine learning algorithm was trained, also has the advantage that the time until the machine learning algorithm can actually be used to classify objects in a vehicle environment can be reduced, while at the same time resources required for (re)training or optimizing the machine learning algorithm or making it more robust, such as storage capacities, can be saved.

In summary, the present invention provides a method for testing the robustness of a machine learning algorithm, which can check the influence of external factors or interventions on the control of the vehicle and increase the safety of controlling the vehicle based on the machine learning algorithm.

The described embodiments and refinements may be combined with one another as desired.

Further possible designs, refinements and implementations of the invention also include combinations of features of the invention described previously or below with regard to the exemplary embodiments that are not explicitly mentioned.

### BRIEF DESCRIPTION OF THE DRAWINGS

The accompanying drawings are intended to provide a better understanding of the embodiments of the invention. They illustrate embodiments and, in connection with the description, serve to explain principles and concepts of the invention.

Other embodiments and many of the advantages mentioned are shown in the drawings. The illustrated elements of the drawings are not necessarily shown to scale with respect to one another.

The figures show:

FIG. 1 a flowchart of a method for testing the robustness of a machine learning algorithm for classifying objects in an environment of a motor vehicle according to embodiments of the invention; and

FIG. 2 a schematic block diagram of a system for testing the robustness of a machine learning algorithm for classifying objects in an environment of a motor vehicle according to embodiments of the invention.

In the figures of the drawings, identical reference numbers denote identical or functionally identical elements, parts or components, unless stated otherwise.

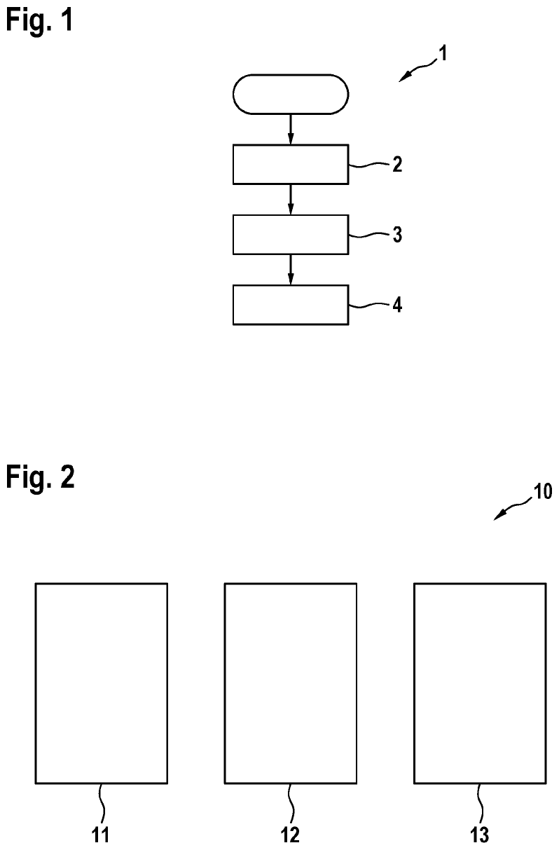

FIG. 1 shows a flowchart of a method for testing the robustness of a machine learning algorithm for classifying objects in an environment of a motor vehicle 1 according to embodiments of the invention.

In particular, FIG. 1 shows a, method for testing the robustness of a machine learning algorithm for classifying objects in an environment of a motor vehicle 1, wherein the machine learning algorithm is trained to classify objects in image data representing an environment of the motor vehicle.

To control a motor vehicle, or functions of a motor vehicle or an autonomously driving vehicle using a machine learning algorithm, wherein the machine learning algorithm is trained to classify objects representing image data in an environment of the motor vehicle, environmental data is usually captured by one or more environmental sensors of the motor vehicle. The environmental sensors may be cameras, radar sensors and/or LIDAR sensors, for example. The data from the individual sensors may then be linked to each other, and a machine learning algorithm trained accordingly based on labeled or provided with corresponding information can classify objects in the linked data. The classified data may then be transmitted to a control software for controlling the motor vehicle.

However, particularly when controlling a motor vehicle, high requirements are placed on the safety and thus also on the robustness of such a machine learning algorithm in order to avoid safety-critical situations as much as possible.

FIG. 1 shows a method 1, wherein, in a first step 2, image data showing an environment of the motor vehicle is provided, wherein the image data contain a depiction of at least one object, wherein in a step 3, the depiction of the at least one object is modified such that it appears distorted, and wherein, in a step 4, a control of the motor vehicle is simulated based on objects classified by the machine learning algorithm in the modified depiction of the at least one object in order to test the robustness of the machine learning algorithm.

Method 1 is thus based on a simulation-based approach for testing the driving function of the motor vehicle, or in order to check the robustness of the algorithm against changes in the conditions or changes in the detected environment of the motor vehicle.

Thus, a method 1 is specified that can be used to identify or detect safety-relevant or safety-critical aspects early on, particularly during the development of the machine learning algorithm. Based on the corresponding test results, it can be further checked whether the algorithm is robust enough against external influences, such as attacks from the outside, and thus suitable for controlling a motor vehicle.

The ability to respond early to potential safety-relevant aspects at an early stage, wherein the method 1 can be used without knowledge of the structure of the machine learning algorithm, of the type of training method and of the available data with which the machine learning algorithm was trained, also has the advantage that the time until the machine learning algorithm can actually be used to classify objects in a vehicle environment can be reduced, while at the same time resources required for (re)training or optimizing the machine learning algorithm or making it more robust, such as storage capacities, can be saved.

Overall, a method 1 is specified that can reliably test the robustness of a machine learning algorithm for classifying objects in a motor vehicle's environment without significant effort.

For example, the machine learning algorithm can be a classifier based on artificial neural network.

According to the embodiments of FIG. 1, the step 3 of modifying the depiction of the at least one object may comprise modifying the depiction of the at least one object such that the object is incorrectly classified by the machine learning algorithm, and/or modifying the depiction of the at least one object based on how the object could be altered by a third party, and/or modifying the depiction of the at least one object based on different light and/or weather conditions.

For example, the depiction may be modified such that a stop sign is incorrectly classified as a priority sign by the machine learning algorithm, that it is simulated that a sticker or comparable object has been affixed to a road sign, or that it is perceived differently due to other solar irradiation.

The modifying of the depiction in step 3 may be done, for example, by an image processing algorithm, wherein the image processing algorithm may modify the depiction, for example, such that it can simulate that a sticker is affixed to a classified road sign, or a brightness of the depiction may be adjusted in order to simulate different light intensities.

In addition, modifying the depiction of the at least one object may also be based on an algorithm of machine learning that is trained to simulate external interventions. In particular, the corresponding machine learning algorithm may be trained to generate artifacts, spots, or noise based on corresponding labeled training data, which is added to the depiction.

According to the embodiments of FIG. 1, the image data is further sensor data recorded by environmental sensors of the motor vehicle.

The corresponding test or review results can then be used, for example, to (re)train or optimize the machine learning algorithm, for example, in order to as far as possible exclude safety-critical situations when controlling the vehicle due to changed conditions or interventions in the detected environmental data.

The method for testing the robustness of the machine learning algorithm can further be implemented as a closed-loop method, wherein the robustness or errors of the machine learning algorithm can be analyzed in several iteration loops or repeats with slightly changed depictions, as well as an open-loop method.

In addition, during the development phase, various tests or inspections can be carried out with different settings, for example different vehicle speeds or different camera angles.

FIG. 2 shows a block diagram of a system for testing the robustness of a machine learning algorithm for classifying objects in an environment of a motor vehicle 10 according to embodiments of the invention.

In particular, FIG. 2 again shows a system for testing the robustness of a machine learning algorithm for classifying objects in an environment of a motor vehicle 10, wherein the machine learning algorithm is trained to classify objects in image data representing an environment of the motor vehicle.

As FIG. 2 shows, the system thereby comprises a provisioning unit 11, which is configured to provide image data showing an environment of the motor vehicle, wherein the image data contain a depiction of at least one object, a modification unit 12, which is configured to modify the depiction of the at least one object such that it appears distorted, and a simulation unit 13, which is configured to simulate a control of the motor vehicle based on objects classified by the machine learning algorithm in the modified depiction of the at least one object in an environment in order to test the robustness of the machine learning algorithm.

The supply unit can be a receiver, for example, which is designed to receive the corresponding data. The modification unit and the simulation unit may furthermore be implemented, for example, based on code that is stored in a memory and can be executed by a processor.

According to the embodiments of FIG. 2, the modification unit 12 is in turn configured to modify the depiction of the at least one object such that the object is incorrectly classified by the machine learning algorithm and/or based on how the object could be altered by a third party and/or based on different light and/or weather conditions.

In particular, the modification unit 12 is configured to apply an image processing algorithm to modify the depiction.

In addition, the modification unit 12 is configured to apply a machine learning algorithm trained to simulate external interventions to modify the depiction.

According to the embodiments of FIG. 2, the image data is in turn further sensor data recorded by environmental sensors of the motor vehicle.

In addition, the system 10 shown is configured to perform a method described above for testing the robustness of a machine learning algorithm to classify objects in an environment of a motor vehicle.

1. A method for testing a robustness of a machine learning algorithm for classifying objects in an environment of a motor vehicle, the machine learning algorithm trained to classify objects in image data representing an environment of the motor vehicle, the method comprising:
providing image data showing the environment of the motor vehicle, the image data containing a depiction of at least one object;
modifying the depiction of the at least one object to appear distorted; and
simulating a control of the motor vehicle based on objects classified by the machine learning algorithm in the modified depiction of the at least one object in order to test the robustness of the machine learning algorithm.

2. The method according to claim 1, wherein modifying the depiction of the at least one object comprises:
modifying the depiction of the at least one object such that the object is incorrectly classified by the machine learning algorithm,
modifying the depiction of the at least one object based on how the object could be altered by a third party, and/or
modifying the depiction of the at least one object based on different light and/or weather conditions.

3. The method according to claim 1, wherein modifying the depiction of the at least one object comprises applying an image processing algorithm.

4. The method according to claim 1, wherein modifying the depiction of the at least one object comprises applying a machine learning algorithm that is trained to simulate external interventions.

5. The method according to claim 1, wherein the image data is sensor data recorded by environmental sensors of the motor vehicle.

6. A method for optimizing a machine learning algorithm for classifying objects in an environment of a motor vehicle, the machine learning algorithm trained to classify objects in image data representing an environment of the motor vehicle, the method comprising:
testing a robustness of a trained algorithm of the machine learning algorithm by the method according to claim 1 in order to provide test results; and
optimizing the machine learning algorithm based on the provided test results.

7. A method for controlling a motor vehicle based on a machine learning algorithm, the machine learning algorithm trained to classify objects in image data representing an environment of the motor vehicle, the method comprising:
providing the machine learning algorithm to classify objects in the environment of the motor vehicle, the machine learning algorithm optimized by the method according to claim 6; and
controlling the motor vehicle based on the provided machine learning algorithm.

8. A system for testing a robustness of a machine learning algorithm for classifying objects in an environment of a motor vehicle, comprising:
a processor configured to implement a machine learning algorithm trained to classify objects in image data representing the environment of the motor vehicle,
wherein the processor is configured to execute the method according to claim 1.

9. A system for optimizing a machine learning algorithm for classifying objects in an environment of a motor vehicle, the machine learning algorithm trained to classify objects in image data representing the environment of the motor vehicle, the system comprising:
a system for testing a robustness of the machine learning algorithm for classifying objects in the environment of the motor vehicle according to claim 8, which is configured to test the robustness of the trained machine learning algorithm in order to provide test results, and
an optimization unit configured to optimize the machine learning algorithm based on the provided test results.

10. A system for controlling a motor vehicle based on a machine learning algorithm, the machine learning algorithm trained to classify objects in image data representing an environment of the motor vehicle, the system comprising:
a provisioning unit configured to provide the machine learning algorithm for classifying objects in the environment of the motor vehicle, wherein the machine learning algorithm has been optimized by a system for optimizing a machine learning algorithm for classifying objects in the environment of a motor vehicle according to claim 9; and
a control unit configured to control the motor vehicle based on the provided machine learning algorithm.

11. The method according to claim 1 wherein a computer program includes program code configured to execute the method when the program code is executed on a computer.

12. A non-transitory computer-readable data carrier including the program code according to claim 11.
